(19) United States
(12) Patent Application Publication
(10) Pub. No.: US 2025/0038000 A1
(43) Pub. Date: Jan. 30, 2025

(54) SiC TRENCH BOTTOM CORNER ROUNDING

(71) Applicant: Applied Materials, Inc., Santa Clara, CA (US)

(72) Inventors: Qintao ZHANG, Mt Kisco, NY (US); Ludovico MEGALINI, Mountain View, CA (US); Wei ZOU, Lexington, MA (US); Hans-Joachim L. GOSSMANN, Summit, NJ (US); William O. CHARLES, Winchester, MA (US)

(73) Assignee: Applied Materials, Inc., Santa Clara, CA (US)

(21) Appl. No.: 18/227,286

(22) Filed: Jul. 27, 2023

(51) Int. Cl. H01L 21/04; H01L 21/266; H01L 21/306; H01L 29/40

(52) U.S. Cl. CPC H01L 21/0475; H01L 21/266; H01L 21/30604; H01L 29/401

(57) ABSTRACT

Disclosed herein are methods for forming MOSFET trenches with improved corner properties. In some embodiments, a method may include providing a device structure including an epitaxial layer and a hard mask over the epitaxial layer, and forming a trench through the well and the epitaxial layer, wherein the trench is defined by a sidewall, a bottom, and a corner at an intersection of the sidewall and the bottom. The method may further include implanting the device structure by delivering ions into the corner and into the bottom of the trench, and etching the trench to increase rounding of the corner.

### FIELD OF THE DISCLOSURE

The present embodiments relate to semiconductor device patterning, and more particularly, to forming transistors with increased SiC trench bottom corner rounding.

### BACKGROUND OF THE DISCLOSURE

Low voltage power metal-oxide-semiconductor field-effect transistors (MOSFETs) are often used in load switching applications where reduction of the on-resistance (R_{ds}) of the device is desirable. In some applications, the R_{ds}A of the device is minimized, where R_{ds}A is the on-resistance of the device multiplied by the active area of the device. Additionally, low voltage power MOSFETs are commonly used in high frequency DC-DC applications.

Trench MOSFET scaling to improve device performance is a continuous goal. In some prior approaches, a 2-step plasma etch process is used for producing round-cornered SiC trenches. However, this approach suffers from tilted sidewalls, a slower etch rate, and pitch-dependent curvature.

Accordingly, improved trench formation approaches are needed to maximize scalability.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include providing a device structure including an epitaxial layer and a hard mask over the epitaxial layer, and forming a trench through the well and the epitaxial layer, wherein the trench is defined by a sidewall, a bottom, and a corner at an intersection of the sidewall and the bottom. The method may further include implanting the device structure by delivering ions into the corner and into the bottom of the trench, and etching the trench to increase rounding of the corner.

In another aspect, a method of forming a transistor may include providing a device structure including a well in an epitaxial layer, and a hard mask over the well, and forming a trench through the well and the epitaxial layer, wherein the trench is defined by a sidewall, a bottom, and a corner at an intersection of the sidewall and the bottom. The method may further include amorphizing the trench by delivering ions into a surface of the corner and into a surface of the bottom of the trench, and etching the trench to increase rounding of the corner, wherein the etching is performed while the hard mask is present over the well.

In yet another aspect, a method of forming a silicon carbide trench may include forming a hard mask over an epitaxial layer, and forming a trench through the epitaxial layer, wherein the trench is defined by a sidewall, a bottom, and a corner at an intersection of the sidewall and the bottom. The method may further include amorphizing the trench by delivering ions into a surface of the corner and into a surface of the bottom of the trench, and etching the trench to increase rounding of the corner, wherein the etching is performed while the hard mask is present over the well.

### BRIEF DESCRIPTION OF THE DRAWINGS

The accompanying drawings illustrate exemplary approaches of the disclosure, including the practical application of the principles thereof, as follows:

FIGS. 1-7 illustrate side cross-sectional views of processes to form a SiC trench device according to embodiments of the present disclosure;

FIGS. 8-9 illustrate side cross-sectional views of processes to form a SiC trench device according to embodiments of the present disclosure;

FIGS. 10A-12B are images of an example SiC trench during processing according to embodiments of the present disclosure; and

FIG. 13 illustrates a schematic diagram of a processing apparatus according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods and devices in accordance with the present disclosure will now be described more fully hereinafter with reference to the accompanying drawings, where various embodiments are shown. The methods and devices may be embodied in many different forms and are not to be construed as being limited to the embodiments set forth herein. Instead, these embodiments are provided so the disclosure will be thorough and complete, and will fully convey the scope of the methods to those skilled in the art.

Embodiments described herein advantageously enable implant-based trench bottom corner rounding for a SiC trench device (e.g., MOSFET). As will be described herein, the bottom corner rounding is fully defined by implantation and, therefore, doesn't impact trench etch rate, is trench geometry independent, and permits tuning of corner rounding through implant species, energy and tilt-angle selection.

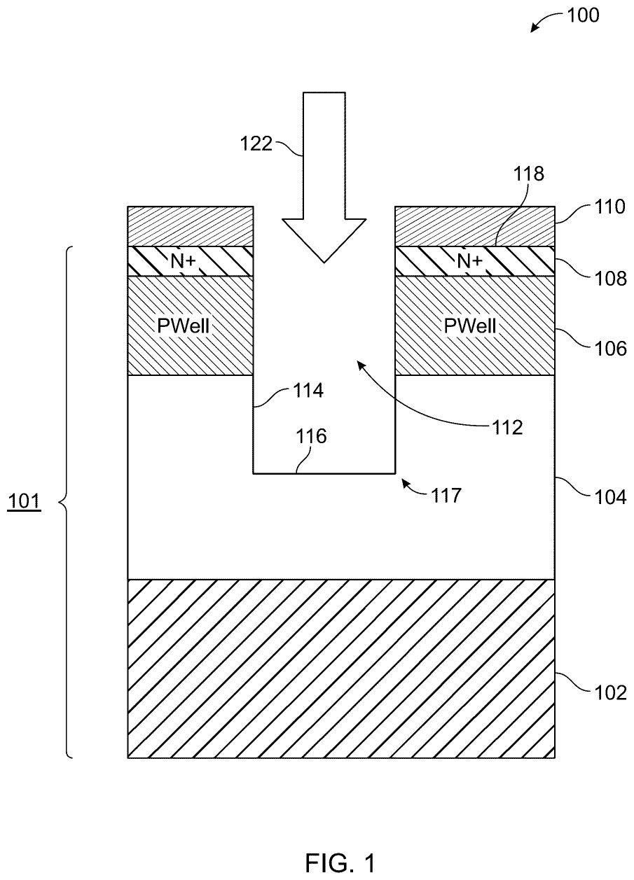

FIG. 1 is a side cross-sectional view of an example device 100, such as a MOSFET, according to one or more embodiments described herein. The device 100 may include a device structure 101 having a substrate 102, an epitaxial layer 104, a well 106, and a source region or layer 108. Although non-limiting, the epitaxial layer 104 may be a silicon carbide (SiC) n-type drift layer, the well 106 may be a p-type well, and the source layer 108 may be an N⁺ source layer. In other embodiments, the source layer 108 may include N+ and P+ regions next to each other, wherein P+ serves as a PWell contact and N+ serves as the source layer. As further shown, a hardmask 110 may be provided over the device structure 101, e.g., directly atop the source layer 108.

Although not shown, one or more p-type isolation shields may be provided between adjacent trenches, e.g., in the case the device 100 is a dual trench gate transistor. Furthermore, although shown as a single layer, the epitaxial layer 104 may include multiple layers in other embodiments. As known, the well 106 may be formed using a plurality of doping steps or epitaxy steps. It will be appreciated that layers and elements of device 100 are non-limiting and provided for the purposes of demonstrating certain aspects of the disclosure. Other SiC MOSFET structures are possible in alternative embodiments.

As further shown, one or more trenches 112 may be formed in the device 100, e.g., using one or more blocking and vertical etch processes 122 to form a sidewall 114 with a slope of approximately 80 to 90 degrees relative to a plane defined by a top surface 118 of the device structure 101. The trenches 112 may be defined, in part, by the sidewall 114, a bottom 116, and a corner 117 at the intersection of the sidewall 114 and the bottom 116. In some embodiments, the trench 112 may be formed after the well 106, the source layer 108, and the hardmask 110 are formed.

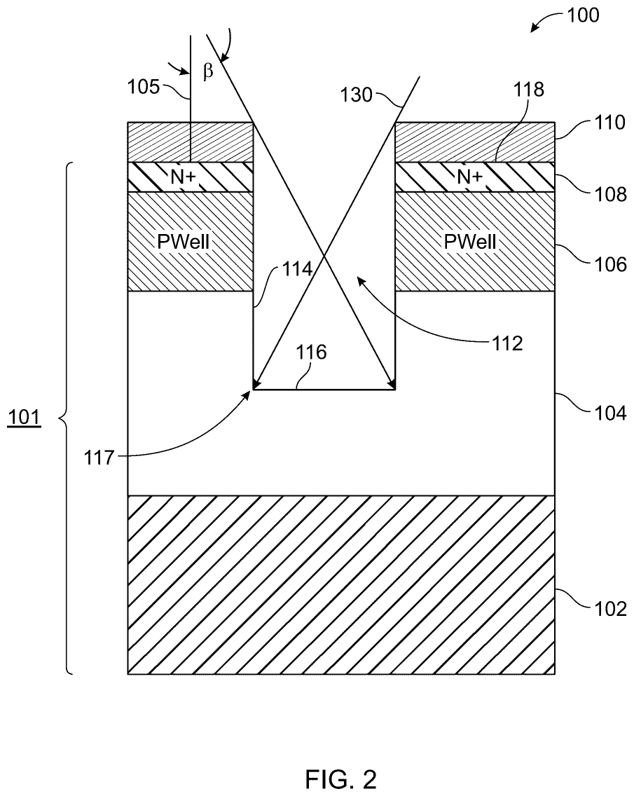

As shown in FIG. 2, a first an ion implant 130 may be performed to the device 100 to form a treated layer along all or just a portion of the trench 112. More specifically, the treated layer may be an amorphized area/layer of one or more exposed surfaces of the trench 112. In various embodiments, the treated layer may be formed along the sidewall(s) and bottom of the epitaxial layer 104, along the sidewall(s) of the epitaxial layer 104 and the well 106, or along the sidewall(s) of the epitaxial layer 104, the well 106, and the source layer 108. Although non-limiting, the first ion implant 130 may include one or more beamline implants delivered at a pre-defined angle, a predefined energy, a predefined dose, etc. For example, one or more implantation ion species, (e.g., oxygen, neon, argon, crypton, arsenic, germanium) can be used during the first ion implant 130. In some embodiments, the first ion implant 130 is performed at a cold implant temperature, e.g., below 0 degree C., which enables amorphization using a relatively lighter species, and allows for a lower dose and thus less damage left over beyond the amorphization interface. This may be particularly true at temperatures of approximately −100° C. Advantageously, tunability of corner rounding through implant species selection is possible, wherein heavier ions generally result in sharper angles for the corner(s) 117. It is also possible to tune the rounding of corners 117 with the implant angle and/or energy.

Furthermore, the first ion implant 130 may be delivered to the device structure 101 at a non-zero angle of inclination β relative to a perpendicular 105 extending from the top surface 118 of the device structure 101. The angle of inclination β, or “critical tilt-angle,” may be selected so the first ion implant 130 does not impact the bottom 116 of the trench 112, and may be calculated analytically. The angle of inclination β may vary in other embodiments, e.g., by +/−45° so the ion implant 130 impacts more or less of the sidewall 114. Furthermore, the device structure 101 and/or the beam angle may be twisted to a degree, such as 30° relative to a direction perpendicular to the page, to allow beams entering into the trench 112 at a controlled angle. Still furthermore, the device structure 101 may be rotated during or between successive implants, e.g., about a central axis normal to the top surface 118 of the device structure 101. Although non-limiting, the device structure 101 may be rotated between each implant process by 45°, 90°, 180°, etc.

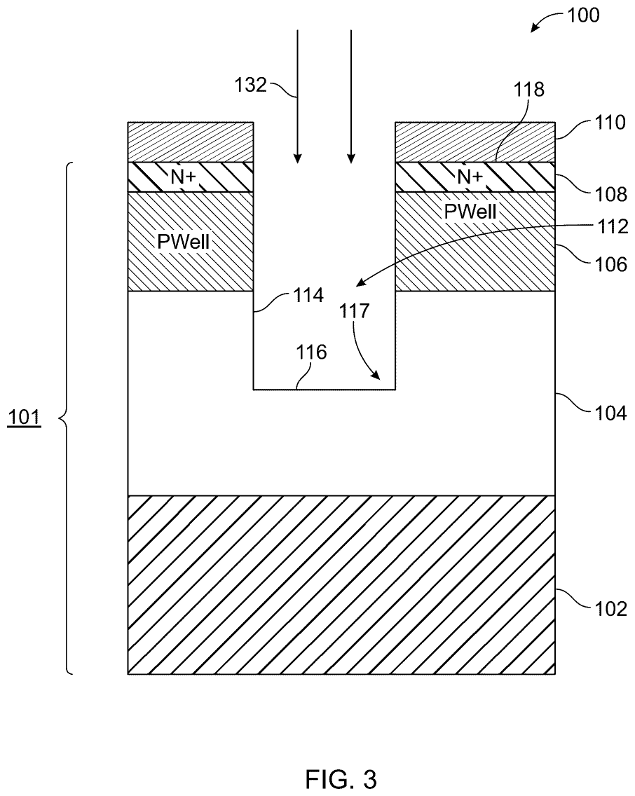

As shown in FIG. 3, a second implant 132 may be performed to the device 100 to further form the treated layer along the bottom 116 of the trench 112. Although non-limiting, the second ion implant 132 may include one or more beamline implants delivered at a pre-defined angle (e.g., vertical/perpendicular to the plane defined by the top surface 118 of the device structure 101), and at a predefined energy and dose. For example, one or more implantation ion species, (e.g., neon, argon, crypton, arsenic, germanium) can be used during the second ion implant 132. The implantation ion species may be the same or different as used during the first ion implant 130. In some embodiments, the second ion implant 132 may also be performed at a cold implant temperature, e.g., below 0° C.

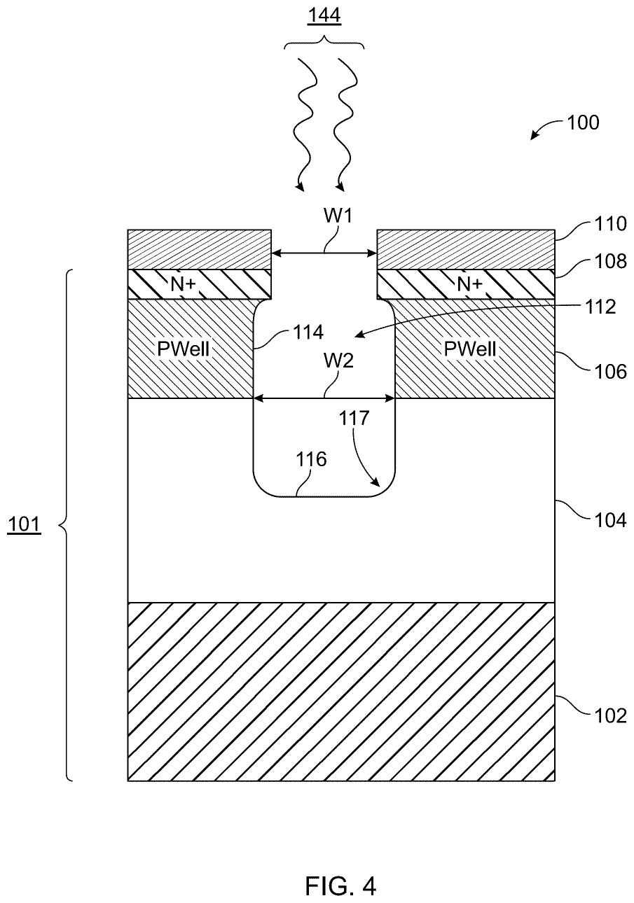

As shown in FIG. 4, an etch process 144 may be performed on the device structure 101 to remove the treated layer from the sidewall 114, the bottom 116, and the corners 117 of the trench 112. More specifically, in some embodiments, the etch process 144 is a wet etch operable to remove the treated layer along the well 106 and the epitaxial layer 104 to increase a width (W2) of the trench bottom relative to a trench opening width (W1) defined by the hardmask 110. In some embodiments, the etch process 144 may also remove an exposed surface portion of the source layer 108. Because of the first implant 130 and/or the second implant 132, the wet etch rate to those portions of the trench 112 impacted by the implants is increased, and thus rounding of the corners 117 is improved. Said another way, the corner rounding may be made more gradual, and the radius of curvature greater, following the etch process 144. Furthermore, a surface defined by the bottom 116 of the trench may remain substantially flat as a result the etch process 144.

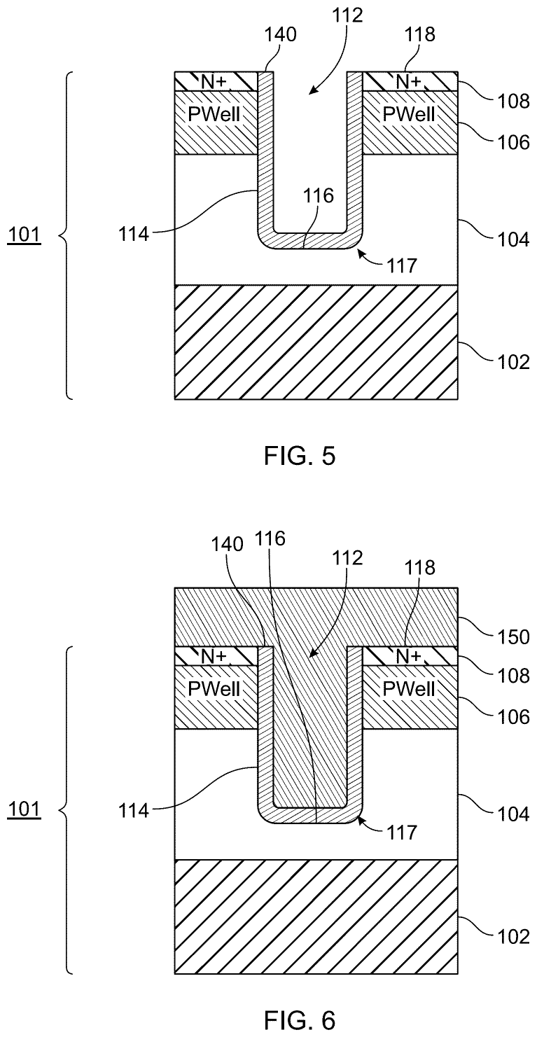

Next, processing of the device 100 may continue as known, e.g., by performing a P+ contact implant, annealing the device, and depositing a polysilicon gate material within the trench 112. More specifically, as shown in FIG. 5, the hardmask 110 has been removed, and a gate oxide layer 140 is formed over the device structure 101, including within the trench 112. Although not shown, the gate oxide layer 140 may also be formed over the top surface 118 of the device structure 101 and then removed, e.g., via CMP. In some embodiments, the gate oxide layer 140 is formed by a thermal oxidation process to device 100 to form a uniform-thickness oxide along the sidewall 114, the bottom 116, and the corners 117.

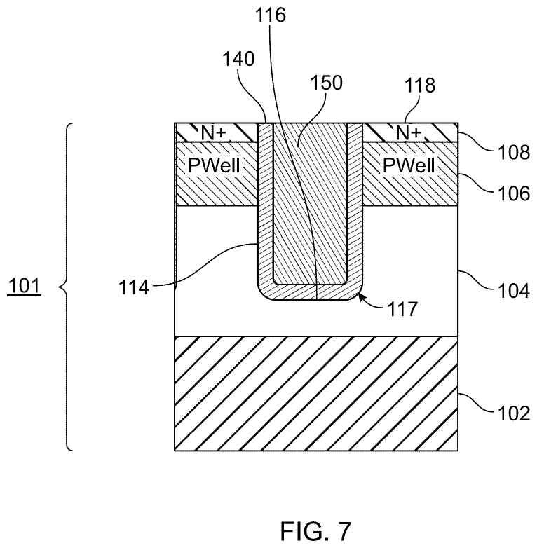

As demonstrated in FIG. 6, a gate material 150 may be formed over the device structure 101 including within the trench 112. In some embodiments, the gate material 150 may be a polysilicon gate refill deposited over the device 100 and then planarized (e.g., via CMP) or etched back selective to the top surface 118 of the device structure 101, as shown in FIG. 7. Although non-limiting, in various embodiments, the gate material 150 may be a p-type or n-type polysilicon, which is doped.

In some embodiments, a second gate material (not shown) may be formed over the gate material 150 to form a split gate, wherein the gate material is separated from the second gate material by an isolation layer. Although non-limiting, the gate material and the second gate material may be different materials, wherein the first gate material may be a p-type polysilicon, and the second gate material may be an active n-type polysilicon.

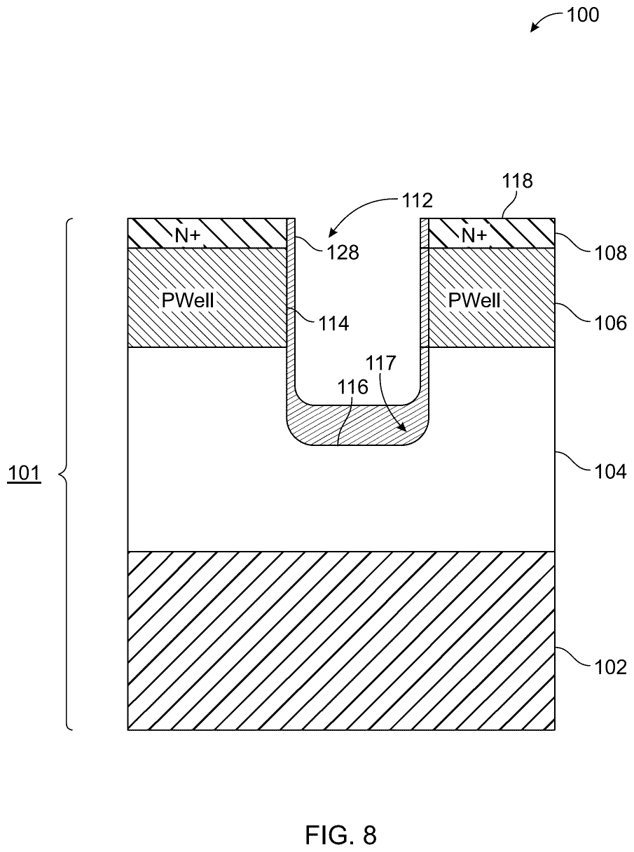

Referring to FIG. 8, another non-limiting embodiment of the present disclosure is demonstrated. Following the second ion implant 132, demonstrated in FIG. 3, the hardmask 110 is removed, and an optional sacrificial oxide layer 128 may be formed over the device 100, including within the trench 112. In some embodiments, the sacrificial oxide layer 128 is formed along the sidewall 114, the bottom 116, and the corners 117 of the trench 112. Although non-limiting, the sacrificial oxide layer 128 may vary in thickness between the sidewall 114 and the bottom 116. For example, as shown, a thickness of the sacrificial oxide layer 128 may be greater along the bottom 116 and in the corners 117 than along the sidewalls 114. Embodiments herein are not limited in this context, however.

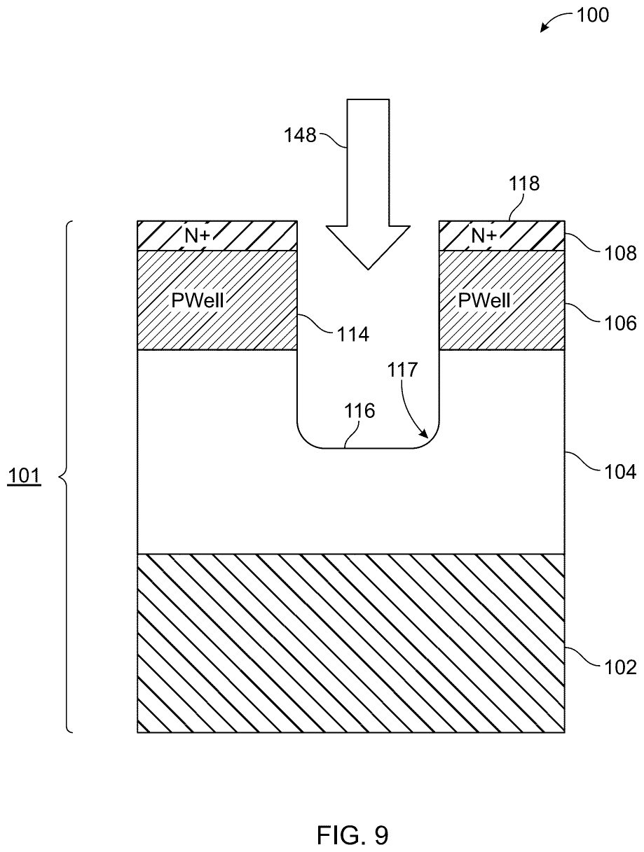

As shown in FIG. 9, the sacrificial oxide layer 128 may then be removed, e.g., using an etch process 148, resulting in increased rounding between the sidewall 114 and the bottom 116. Said another way, the rounding of corners 117 may be more gradual, and the radius of curvature greater, following the sacrificial oxide removal. In this embodiment, the wet etch step demonstrated in FIG. 4 may be skipped because the implanted area of the trench 112 can be oxidized significantly faster and, thus, be fully removed using an HF etchant during the sacrificial oxide removal. Although not shown, processing of the device 100 may then continue as known, e.g., by performing a P+ contact implant, annealing the device, depositing a polysilicon gate material within the trench 112, etc.

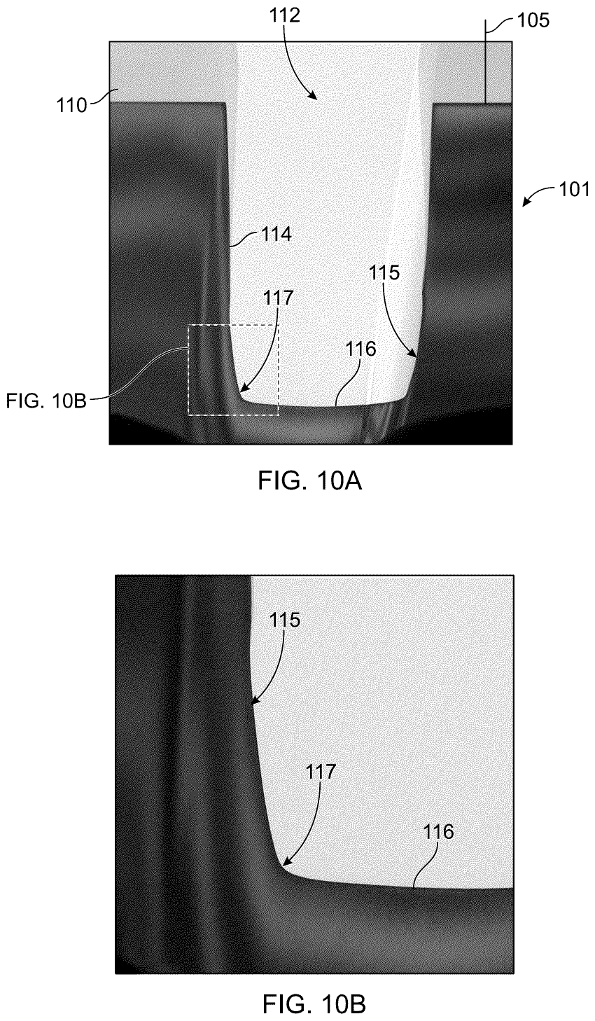

Referring to FIGS. 10A-12B, SiC trench bottom corner rounding will be shown and described in greater detail. FIGS. 10A and 10B demonstrate the device structure 101 and the hardmask 110 following formation of the trench 112. As shown, a lower portion 115 of the sidewall 114 may slope at an angle relative to the perpendicular 105, and the bottom 116 may be slightly curved. Furthermore, the corners 117 may be relatively sharp.

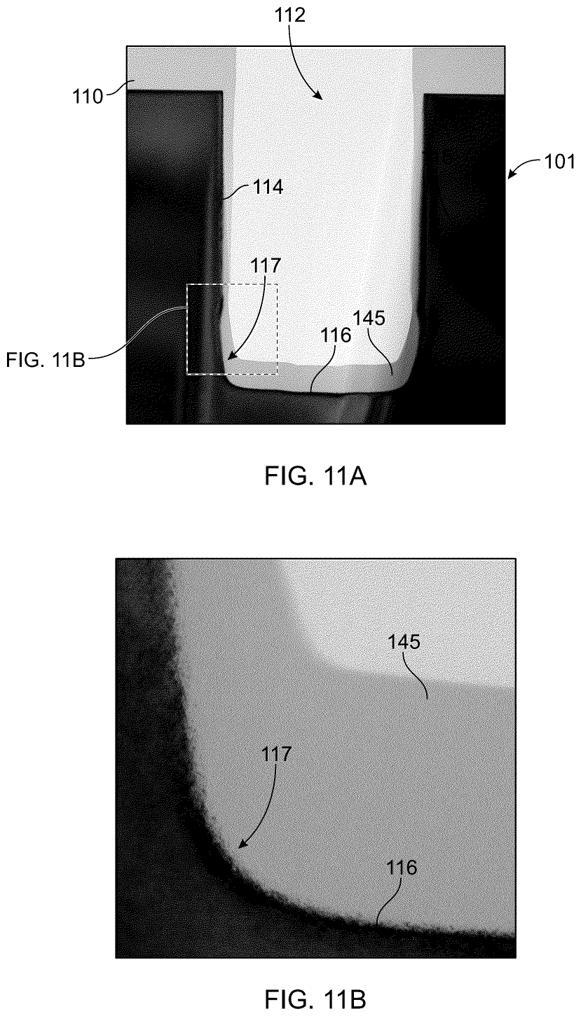

FIGS. 11A and 11B demonstrate the device structure 101 following the first ion implant 130 and the second ion implant 132 to form an amorphized layer 145 along the exposed surfaces of the trench 112. As described above, the amorphized layer 145 may increase an etch rate of the trench 112 surfaces. Although non-limiting, the first ion implant 130 may include oxygen ions delivered at 60 KeV 5E15 with a tilt of approximately 15°, while the second ion implant 132 may also be oxygen ions delivered at 60 KeV 5E15 with a tilt of approximately 0°.

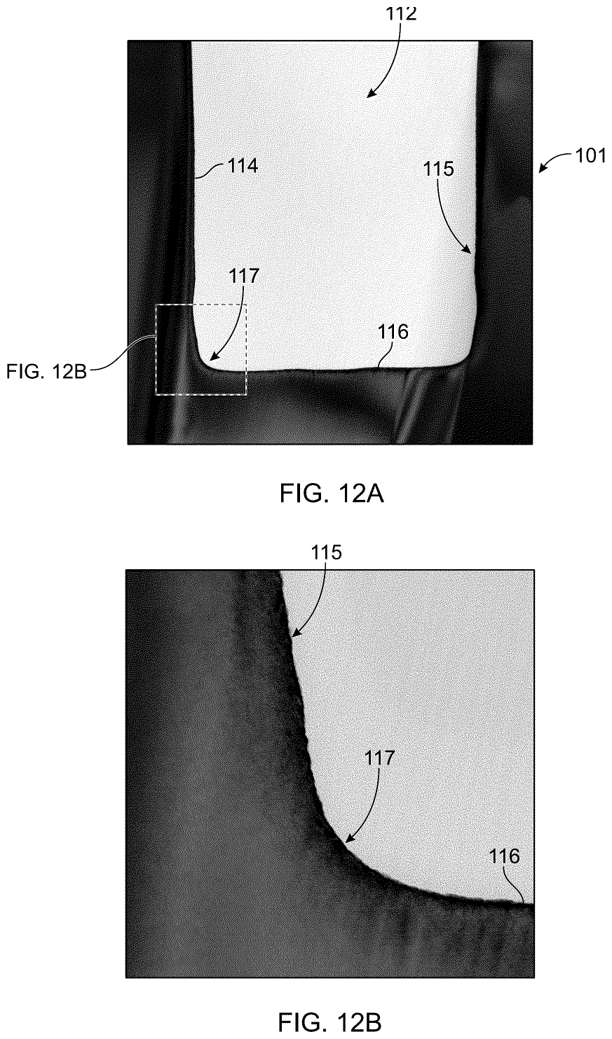

FIGS. 12A and 12B demonstrate the device structure 101 following an etch process, such as the wet etch 144 demonstrated in FIG. 4. Because of the first implant 130 and/or the second implant 132 to form the amorphized layer 145, the wet etch rate to those portions of the trench 112 impacted by the implants is increased. Advantageously, as a result, rounding of the corners 117 is improved by making the corner rounding more gradual. Furthermore, the surface defined by the bottom 116 of the trench 112 is further flattened, and the lower portion 115 of the sidewall 114 is made more vertical.

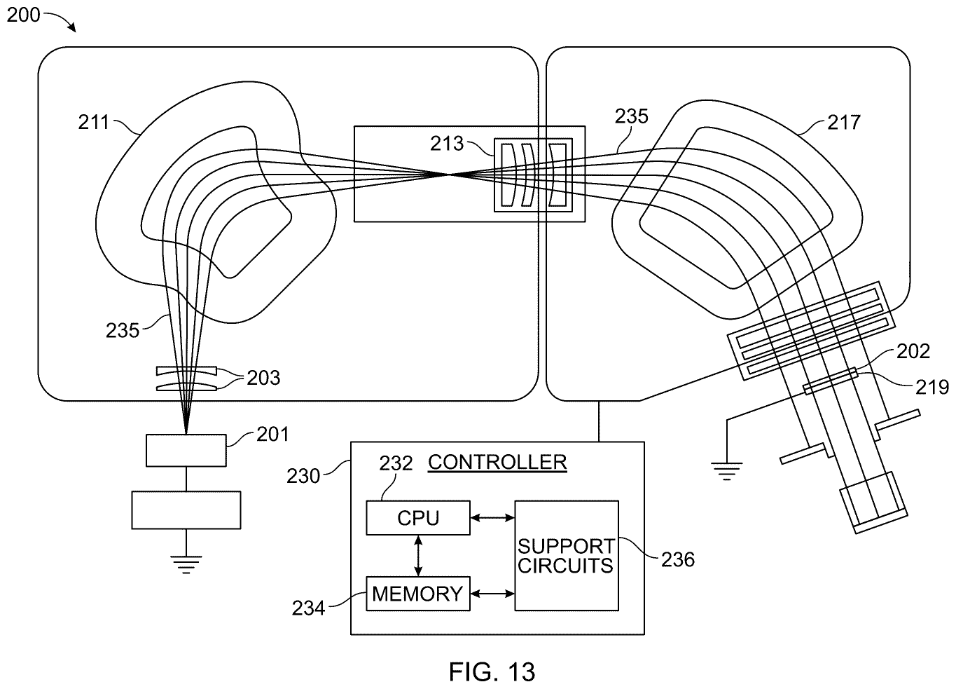

FIG. 13 illustrates a schematic diagram of a processing apparatus 200 useful to perform processes described herein. One example of a beam-line ion implantation processing apparatus is the Varian VIISTA® Trident, available from Applied Materials Inc., Santa Clara, CA. The processing apparatus 200 may include an ion source 201 for generating ions. For example, the ion source 201 may provide an ion implant, such as the first ion implant 130 demonstrated in FIG. 2 and the second ion implant 132 demonstrated in FIG. 3. The ion source 201 may also provide an ion etch, such as the etch process described with respect to FIG. 9.

The processing apparatus 200 may also include a series of beam-line components. Examples of beam-line components may include extraction electrodes 203, a magnetic mass analyzer 211, a plurality of lenses 213, and a beam parallelizer 217. The processing apparatus 200 may also include a platen 219 for supporting a substrate 202 to be processed. The substrate 202 may be the same as the substrate 102 described above. The substrate 202 may be moved in one or more dimensions (e.g. translate, rotate, tilt, etc.) by a component sometimes referred to as a “roplat” (not shown). It is also contemplated that the processing apparatus 200 may be configured to perform heated implantation processes to provide for improved control of implantation characteristics, such as the ion trajectory and implantation energy utilized to dope the substrate.

In operation, ions of the desired species, for example, dopant ions, are generated and extracted from the ion source 201. Thereafter, the extracted ions 235 travel in a beam-like state along the beam-line components and may be implanted in the substrate 202. Similar to a series of optical lenses that manipulate a light beam, the beam-line components manipulate the extracted ions 235 along the ion beam. In such a manner, the extracted ions 235 are manipulated by the beam-line components while the extracted ions 235 are directed toward the substrate 202. It is contemplated that the apparatus 200 may provide for improved mass selection to implant desired ions while reducing the probability of undesirable ions (impurities) being implanted in the substrate 202.

In some embodiments, the processing apparatus 200 can be controlled by a processor-based system controller such as controller 230. For example, the controller 230 may be configured to control beam-line components and processing parameters associated with beam-line ion implantation processes. The controller 230 may include a programmable central processing unit (CPU) 232 that is operable with a memory 234 and a mass storage device, an input control unit, and a display unit (not shown), such as power supplies, clocks, cache, input/output (I/O) circuits, and the like, coupled to the various components of the processing apparatus 200 to facilitate control of the substrate processing. The controller 230 also includes hardware for monitoring substrate processing through sensors in the processing apparatus 200, including sensors monitoring the substrate position and sensors configured to receive feedback from and control a heating apparatus coupled to the processing apparatus 200. Other sensors that measure system parameters such as substrate temperature and the like, may also provide information to the controller 230.

To facilitate control of the processing apparatus 200 described above, the CPU 232 may be one of any form of general-purpose computer processor that can be used in an industrial setting, such as a programmable logic controller (PLC), for controlling various chambers and sub-processors. The memory 234 is coupled to the CPU 232 and the memory 234 is non-transitory and may be one or more of readily available memory such as random access memory (RAM), read only memory (ROM), floppy disk drive, hard disk, or any other form of digital storage, local or remote. Support circuits 236 may be coupled to the CPU 232 for supporting the processor in a conventional manner. Implantation and other processes are generally stored in the memory 234, typically as a software routine. The software routine may also be stored and/or executed by a second CPU (not shown) that is remotely located from the hardware being controlled by the CPU 232.

The memory 234 is in the form of computer-readable storage media that contains instructions, that when executed by the CPU 232, facilitates the operation of the apparatus 200. The instructions in the memory 234 are in the form of a program product such as a program that implements the method of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

It is to be understood that the various layers, structures, and regions shown in the accompanying drawings are schematic illustrations. For ease of explanation, one or more layers, structures, and regions of a type commonly used to form semiconductor devices or structures may not be explicitly shown in a given drawing. This does not imply that any layers, structures, and/or regions not explicitly shown are omitted from the actual semiconductor structures.

In various embodiments, design tools can be provided and configured to create the datasets used to pattern the semiconductor layers of the device 100, e.g., as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading the Detailed Description, the various features and functionality described herein may be implemented in any given application and can be implemented in one or more separate or shared modules in various combinations and permutations. Although various features or elements of functionality may be individually described or claimed as separate modules, one of ordinary skill in the art will understand these features and functionality can be shared among one or more common software and hardware elements.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
providing a device structure including an epitaxial layer and a hard mask over the epitaxial layer;
forming a trench through the epitaxial layer, wherein the trench is defined by a sidewall, a bottom, and a corner at an intersection of the sidewall and the bottom;
implanting the device structure by delivering ions into the corner and into the bottom of the trench;
etching the trench to increase rounding of the corner.

2. The method of claim 1, further comprising removing the hard mask after the trench is etched.

3. The method of claim 1, wherein implanting the trench comprises:
performing a first ion implant at a non-zero angle relative to a perpendicular extending from a plane defined by top surface of the mask; and
performing a vertical, second ion implant.

4. The method of claim 3, wherein implanting the trench further comprises delivering ions of the first ion implant into the sidewall of the trench.

5. The method of claim 1, wherein etching the trench comprises performing a wet etch.

6. The method of claim 1, further comprising:
forming a thermal gate oxide layer within the trench; and
forming polysilicon gate material over the thermal gate oxide.

7. The method of claim 1, further comprising:
forming a sacrificial oxide within the trench;
removing the sacrificial oxide; and
forming a polysilicon gate material within the trench after the annealing.

8. The method of claim 1, further comprising providing a source region over a well, wherein the trench is formed through the epitaxial layer, the well, and the source region.

9. A method of forming a transistor, comprising:
providing a device structure including a well in an epitaxial layer, and a hard mask over the well;
forming a trench through the well and the epitaxial layer, wherein the trench is defined by a sidewall, a bottom, and a corner at an intersection of the sidewall and the bottom;
amorphizing the trench by delivering ions into a surface of the corner and into a surface of the bottom of the trench;
etching the trench to increase rounding of the corner, wherein the etching is performed while the hard mask is present over the well.

10. The method of claim 9, further comprising removing the hard mask after the trench is etched.

11. The method of claim 9, wherein amorphizing the trench comprises:
performing a first ion implant at a non-zero angle relative to a perpendicular extending from a plane defined by top surface of the device structure; and
performing a second ion implant, wherein the ions of the second ion implant are delivered into the surface of the bottom of the trench.

12. The method of claim 9, wherein etching the trench comprises performing a wet etch process.

13. The method of claim 9, further comprising:
forming a thermal gate oxide layer within the trench; and
forming polysilicon gate material over the thermal gate oxide.

14. The method of claim 9, further comprising:
forming a sacrificial oxide within the trench;
removing the sacrificial oxide; and
forming a polysilicon gate material within the trench after the annealing.

15. The method of claim 9, further comprising providing a source region over the well, wherein the trench is formed through the epitaxial layer, the well, and the source region.

16. A method of forming a silicon carbide trench, the method comprising:
forming a hard mask over an epitaxial layer;
forming a trench through the epitaxial layer, wherein the trench is defined by a sidewall, a bottom, and a corner at an intersection of the sidewall and the bottom;
amorphizing the trench by delivering ions into a surface of the corner and into a surface of the bottom of the trench;
etching the trench to increase rounding of the corner, wherein the etching is performed while the hard mask is present over the epitaxial layer.

17. The method of claim 16, further comprising removing the hard mask after the trench is etched.

18. The method of claim 16, wherein amorphizing the trench comprises:
performing a first ion implant at a non-zero angle relative to a perpendicular extending from a plane defined by top surface of the epitaxial layer; and
performing a second ion implant, wherein the ions of the second ion implant are delivered into the surface of the bottom of the trench.

19. The method of claim 16, wherein etching the trench comprises performing a wet etch process.

20. The method of claim 16, further comprising:
forming a sacrificial oxide within the trench;
removing the sacrificial oxide; and
forming a polysilicon gate material within the trench after the annealing.
